(19) United States
(12) Patent Application Publication
(10) Pub. No.: US 2019/0185998 A1
(43) Pub. Date: Jun. 20, 2019

(54) PLASMA ATOMIC LAYER DEPOSITION APPARATUS AND ATOMIC LAYER DEPOSITION METHOD

(71) Applicant: THE JAPAN STEEL WORKS, LTD., Shinagawa-ku, Tokyo (JP)

(72) Inventors: Keisuke WASHIO, Kanagawa (JP); Tatsuya MATSUMOTO, Kanagawa (JP)

(21) Appl. No.: 16/329,192

(22) PCT Filed: Apr. 24, 2017
(86) PCT No.: PCT/JP2017/016187

§ 371 Date: Feb. 27, 2019

(30) Foreign Application Priority Data
Aug. 31, 2016 (JP) 2016-168992

(51) Int. Cl. C23C 16/44; H01L 51/50; H01L 51/56; C23C 16/455

(52) U.S. Cl. CPC C23C 16/4401; H01L 51/5012; C23C 16/45536; C23C 16/45544; H01L 51/56

(57) ABSTRACT

A plasma atomic layer deposition apparatus capable of improving a film quality of a film formed on a substrate is provided. The atomic layer deposition apparatus is a plasma atomic layer deposition apparatus configured to form the film on the substrate is in an atomic layer unit by generating plasma discharge between a lower electrode BE holding the substrate 15 and a facing upper electrode UE, and has a deposition prevention member CTM made of an insulator surrounding the upper electrode UE but being away therefrom in a plan view.

### TECHNICAL FIELD

The present invention relates to an atomic layer deposition technique.

### BACKGROUND ART

Japanese Patent Application Laid-Open Publication No. 2006-351655 (Patent Document 1) describes a technique in a deposition apparatus using a CVD (Chemical Vapor Deposition) method or a sputtering method, the technique using a deposition prevention plate and covering depositions deposited on an inner wall of a chamber with an amorphous film.

Japanese Patent Application Laid-Open Publication No. 2009-62579 (Patent Document 2) describes a technique arranging a plurality of deposition prevention plates so as to correspond to a plurality of side surfaces inside a film-forming chamber, dividing the deposition prevention plates into a plurality of sections and forming a gap between the adjacent deposition prevention plates.

Japanese Patent Application Laid-Open Publication No. 2012-52221 (Patent Document 3) describes a technique of controlling a flow rate ratio between a flow rate of gas introduced into a sputtering space and a flow rate of gas introduced into a space between an inner wall of a vacuum chamber and a deposition prevention plate on the basis of a pressure value of the sputtering space.

Japanese Patent Application Laid-Open Publication No. 2014-133927 (Patent Document 4) describes a technique of arranging a pair of deposition prevention plates having a plurality of through holes therein so as to be adjacent to an inner wall of a processing room.

Japanese Patent Application Laid-Open Publication No. 2001-316797 (Patent Document 5) describes a technique of attaching a deposition prevention member, which prevents adhesion of a film onto a surface of a substrate carrier, to a bottom surface of the substrate carrier.

### RELATED ART DOCUMENTS

### Patent Documents

Patent Document 1: Japanese Patent Application Laid-Open Publication No. 2006-351655

Patent Document 2: Japanese Patent Application Laid-Open Publication No. 2009-62579

Patent Document 3: Japanese Patent Application Laid-Open Publication No. 2012-52221

Patent Document 4: Japanese Patent Application Laid-Open Publication No. 2014-133927

Patent Document 5: Japanese Patent Application Laid-Open Publication No. 2001-316797

### SUMMARY OF THE INVENTION

### Problems to be Solved by the Invention

An atomic layer deposition method is a film forming method of forming a film on a substrate in an atomic layer unit by alternate supply of a source gas and a reaction gas onto the substrate. Since the film is formed in the atomic layer unit in this atomic layer deposition method, the method has such advantages as excellent step coverage and thickness controllability. On the other hand, in an atomic layer deposition apparatus embodying the atomic layer deposition method, as trade-off of the advantage of the excellent step coverage, the film is easily formed even in a portion from which it is difficult to remove the film without change in film deposition conditions. Because of this point, it is concerned that a film quality of the film formed on the substrate deteriorates due to occurrence of foreign substances caused by peeling of the film formed in the portion from which it is difficult to remove the film without the change in film deposition conditions.

Other objects and novel characteristics will be apparent from the description of the present specification and the accompanying drawings.

### Means for Solving the Problems

An atomic layer deposition apparatus according to one embodiment is an atomic layer deposition apparatus forming a film on a substrate in an atomic layer unit by generating plasma discharge between a first electrode holding the substrate and a second electrode facing the first electrode, and has a deposition prevention member made of an insulator surrounding the second electrode but being away therefrom in a plan view.

### Effects of the Invention

According to an atomic layer deposition apparatus according to one embodiment, a film quality of a film formed on a substrate can be improved.

### BRIEF DESCRIPTIONS OF THE DRAWINGS

FIG. 1 is a cross-sectional view schematically showing an entire configuration of a plasma atomic layer deposition apparatus according to an embodiment;

FIG. 2 is a diagram schematically showing a configuration of a deposition prevention member according to the present embodiment, the deposition prevention member being formed so as to surround an upper electrode but being away therefrom;

FIG. 3 is a schematic view showing a configuration aspect example of the deposition prevention member according to the embodiment;

FIG. 4 is a schematic view showing another configuration aspect example of the deposition prevention member according to the embodiment;

FIG. 5 is a diagram schematically showing a detailed configuration of a portion supporting an upper electrode;

FIG. 6 is diagrams schematically showing a correspondence relation between a cross-sectional configuration and a planar configuration of the portion supporting the upper electrode;

FIG. 7 is a flowchart explaining an atomic layer deposition method according to the embodiment; and

FIGS. 8(a) to (e) are diagrams schematically showing steps of forming the film on the substrate.

### BEST MODE FOR CARRYING OUT THE INVENTION

### <Space for Specific Improvement in Atomic Layer Deposition Apparatus>

For example, in a plasm CVD apparatus, while a plurality of source gases are supplied to a portion between a lower electrode holding a substrate and an upper electrode facing the lower electrode, plasma discharge is generated between a lower electrode and an upper electrode. In this manner, in the plasma CVD apparatus, a film is formed on the substrate by a chemical reaction using active species (radicals) generated by the plasma discharge. At this time, in the plasma CVD apparatus, the film is mainly formed in a region (discharge space) where the plasma discharge is generated. This is because a film material is eventually formed when the active species (radicals) are generated by the plasma discharge from a plurality of source gases while a source gas having characteristics of diffusion difficulty for allowing the source gas to be localized in the discharge space is used as the source gas used in the plasma CVD apparatus. Therefore, the plasma CVD apparatus tends to be difficult to form the film in the portion that is away from the discharge space (the portion where the plasma discharge is not generated).

On the other hand, for example, a plasm atomic layer deposition apparatus forms the film on the substrate in the atomic layer unit by alternately supplying a source gas and a reaction gas into a portion between a lower electrode holding a substrate and an upper electrode facing the lower electrode and generating plasma discharge in the supply of the reaction gas. At this time, the plasm atomic layer deposition apparatus can form a film having excellent step coverage by forming the film in the atomic layer unit. Particularly, in the plasm atomic layer deposition apparatus, a material that easily diffuses is used as the source gas in order to achieve the good step coverage, and each gas (the source gas, a purge gas, and the reaction gas) is alternately supplied while time for sufficient diffusion of each gas into a film-forming container is secured. Therefore, for example, the source gas and the reaction gas spread to not only the substrate but also corners of the film-forming container. Further, in the plasm atomic layer deposition apparatus, in addition to the film formation by the formation of the active species (radicals) by the generation of the plasma discharge from the reaction gas and by the reaction of the active species with the source gas adhered on the substrate, the source gas and the reaction gas tend to react each other even when the active species (radicals) are not generated by the plasma discharge. Therefore, in the plasm atomic layer deposition apparatus, even in a small gap of the film-forming container where the plasma discharge is not generated, the source gas and the reaction gas react to form the film. That is, the atomic layer deposition apparatus has characteristics such that (1) the film is formed in the atomic layer unit, (2) the source gas and the reaction gas spread also to corners of the film-forming container, and (3) the source gas and the reaction gas easily react each other even in the portion where the plasma discharge is not generated. As a result, the film is formed also in the small gap.

As described above, the plasm atomic layer deposition apparatus has characteristics such that the film is undesirably formed in not only the substrate but also the corners including the small gap in the film-forming container. Since the present inventors have found that there is a space for specific improvement in the plasm atomic layer deposition apparatus on the basis of the characteristics, the space for the improvement will be described below.

For example, in the plasm atomic layer deposition apparatus, the upper electrode is supported by, for example, an insulating support member. As described above, the film is undesirably formed even in the corners of the film-forming container, and therefore, the film is formed also in the insulating support member. When a thickness of the film adhered on the insulating support member is large, a part of the adhered film peels off from the insulating support member, and becomes foreign substances. The foreign substances become a cause of deterioration of the film quality of the film formed on the substrate. Because of this, in order to improve the film quality of the film formed on the substrate, it is required to remove the film adhered on the insulating support member.

Regarding this point, for example, it is considered that the film adhered on the insulating support member is removed by, for example, dry etching performed while a cleaning gas made of, for example, NF₃ gas or others is introduced into the film-forming container. However, while the plasm atomic layer deposition apparatus forms the film also in the corners including the small gap in the film-forming container, the dry etching using the cleaning gas removes the film only in the portion where the plasma discharge is generated, and the dry etching is difficult to allow the cleaning gas to spread also to the corners including the small gap in the film-forming container. Further, while an aluminum oxide film (Al₂O₃ film) can be cited as one example of the film formed by the plasm atomic layer deposition apparatus, this aluminum oxide film is difficult to be removed by the dry etching. Therefore, in the dry etching using the cleaning gas in the plasm atomic layer deposition apparatus, it is difficult to remove the film formed also in the corners of the film-forming container, and therefore, it is also difficult to use the dry etching for, for example, the removal of the film adhered on the insulating support member.

Accordingly, for example, it is considered that the insulating support member for fixing the upper electrode is detached, and then, the film adhered on the insulating support member is removed by wet etching. However, when the insulating support member is attached again after the insulating support member is detached and the wet etching is performed, an attachment position of the upper electrode is different from a previous attachment position. In this case, a state of the plasma discharge between the upper electrode and the lower electrode changes. That is, in the method of detaching the insulating support member and performing the cleaning by the wet etching, an attachment position of the insulating support member cannot be reproduced. As a result, the attachment position of the upper electrode supported by the insulating support member changes, and typical film forming conditions in the state of the plasma discharge undesirably changes. This case has a risk of change in the film quality of the film formed on the substrate. Further, in the method of removing the film adhered on the insulating support member by the wet etching, it is required to take out the insulating support member after inside of the film-forming container is released to atmospheric pressure, and maintenance workability is reduced.

From the above description, it is found that it is difficult in the plasm atomic layer deposition apparatus to improve the film quality of the film formed on the substrate while the film adhered on insulating support member supporting the upper electrode is removed without change in the film forming conditions. Accordingly, in the present embodiment, development for removing the film adhered on the insulating support member supporting the upper electrode has been made. A technical concept in the present embodiment having made the development will be described below.

<Entire Configuration of Plasma Atomic Layer Deposition Apparatus>

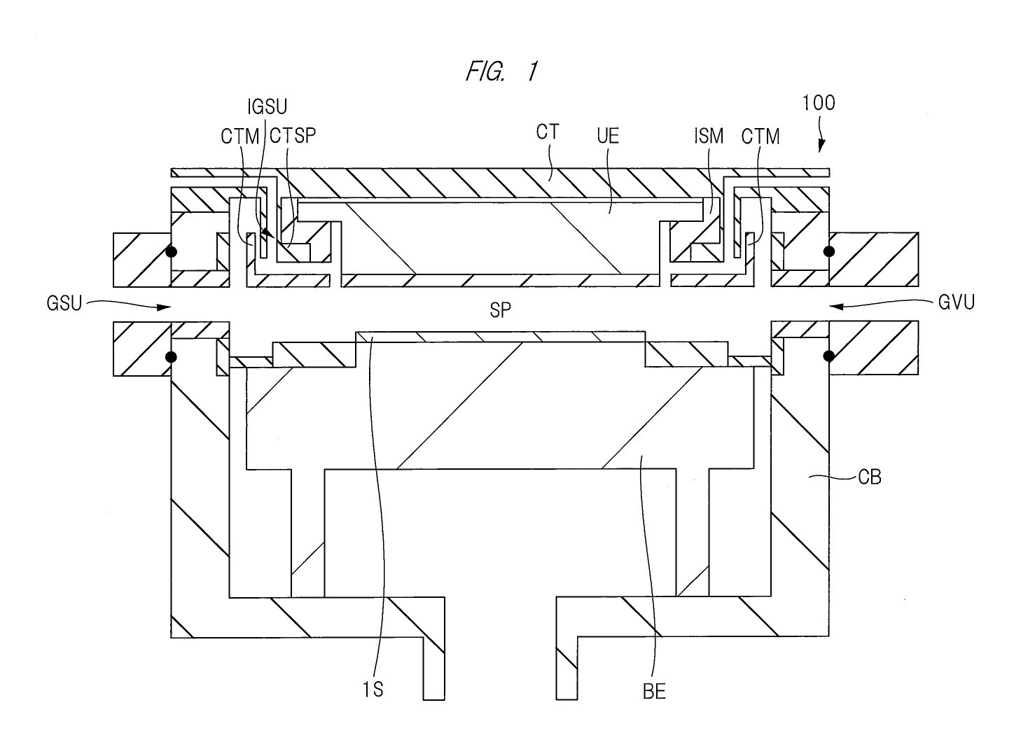

FIG. 1 is a cross-sectional view schematically showing an entire configuration of a plasma atomic layer deposition apparatus 100 according to the present embodiment. The plasma atomic layer deposition apparatus 100 according to the present embodiment is configured to form a film on a substrate 1S in an atomic layer unit by alternate supply of a source gas and a reaction gas. At this time, in order to enhance a reaction activity, the substrate 1S can be heated.

In the present embodiment, TMA (Tri-Methyl-Aluminum) is used as a raw material, and the plasma discharge is performed in order to enhance the reaction activity. In the present embodiment, in order to perform the plasma discharge, a plate electrode is used.

As shown in FIG. 1, the plasma atomic layer deposition apparatus 100 according to the present embodiment has a film-forming container CB. A stage holding the substrate 1S is arranged in this film-forming container CB, and this stage functions as a lower electrode BE. The stage has a heater, and is configured so that a temperature of the substrate 1S can be adjusted. For example, in the case of the plasma atomic layer deposition apparatus 100 according to the present embodiment, the substrate 1S held on the stage is heated to 50° C. to 200° C. And, the film-forming container CB is maintained in a vacuum state.

Next, as shown in FIG. 1, in the film-forming container CB, a gas supply portion GSU supplying the source gas, the purge gas and the reaction gas is formed, and a gas outlet portion GVU exhausting the source gas, the purge gas and the reaction gas is also formed. For example, the gas supply portion GSU and the gas outlet portion GVU are arranged at positions facing each other, and the gas supplied from the gas supply portion GSU goes through a discharge space SP inside the film-forming container CB, and is exhausted from the gas outlet portion GVU.

Further, in the film-forming container CB, an upper electrode UE is arranged so as to interpose the discharge space positioned above the substrate 1S loaded on the lower electrode BE. That is, the upper electrode UE is arranged so as to face the lower electrode BE on which the substrate 1S is loaded. A top panel CT is arranged above the upper electrode UE, and a top-plate supporting portion CTSP for supporting the upper electrode UE is formed in this top panel CT. Further, an insulating support member ISM is arranged so as to be closely adhere to the top-plate supporting portion CTSP, and the upper electrode UE is supported by this insulating support member ISM. As shown in FIG. 1, the plasma atomic layer deposition apparatus 100 according to the present embodiment has a deposition prevention member CTM made of an insulator surrounding the upper electrode UE but being away therefrom in a plan view, and the deposition prevention member CTM is arranged so as to overlap the insulating support member ISM in a plan view.

Subsequently, as shown in FIG. 1, in the top panel CT, an inert gas supply portion IGSU supplying an inert gas such as nitrogen gas into the film-forming container CB is arranged. As described above, in the plasma atomic layer deposition apparatus 100 according to the present embodiment, the gas supply portion GSU supplying the source gas, the purge gas and the reaction gas and the inert gas supply portion IGSU supplying the inert gas are separately arranged.

<Configuration of Deposition Prevention Member>

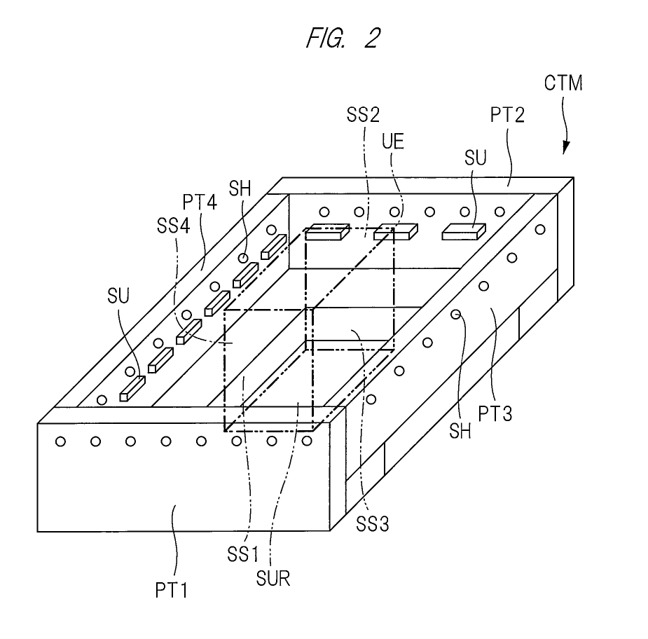

Next, a configuration of the deposition prevention member CTM according to the present embodiment will be described. FIG. 2 is a diagram schematically showing the configuration of the deposition prevention member CTM according to the present embodiment, the deposition prevention member being formed so as to surround the upper electrode UE but being away therefrom. In FIG. 2, a rectangular parallelepiped body shown with a two-dot chain line indicates the schematic configuration of the upper electrode UE. The upper electrode UE shown in FIG. 2 has a surface SUR facing the lower electrode BE shown in FIG. 1, a side surface SS1 crossing the surface SUR, a side surface SS2 positioned at an opposite side of the side surface SS1, a side surfaces SS3 crossing the surface SUR and the side surface SS1, and a side surface SS4 positioned at an opposite side of the side surface SS3. As shown in FIG. 2, the deposition prevention member CTM according to the present embodiment is configured so as to surround the upper electrode UE but being away therefrom. Specifically, the deposition prevention member CTM according to the present embodiment has a part PT1 facing the side surface SS1 of the upper electrode UE, a part PT2 facing the side surface SS2 of the upper electrode UE, a part PT3 facing the side surface SS3 of the upper electrode UE, and a part PT4 facing the side surface SS4 of the upper electrode UE. Meanwhile, in the deposition prevention member CTM according to the present embodiment, as shown in FIG. 2, an opening is formed in a bottom portion of the deposition prevention member CTM so as to expose the surface SUR of the upper electrode UE. As a result, as shown in FIG. 2, each of the parts PT1 to PT4 of the deposition prevention member CTM according to the present embodiment has an “L” shape having a horizontal part and a vertical part.

Here, in each of the parts PT1 to PT4 of the deposition prevention member CTM, a plurality of fixing holes SH in each of which a fixing member is buried and a plurality of convex portions SU each supporting the fixing member are formed. In this manner, the deposition prevention member CTM is supported by the fixing member not shown in FIG. 2. As described above, in the plasma atomic layer deposition apparatus according to the present embodiment, the deposition prevention member CTM surrounding the upper electrode UE is arranged.

<First Configuration Aspect (Unification) of Deposition Prevention Member>

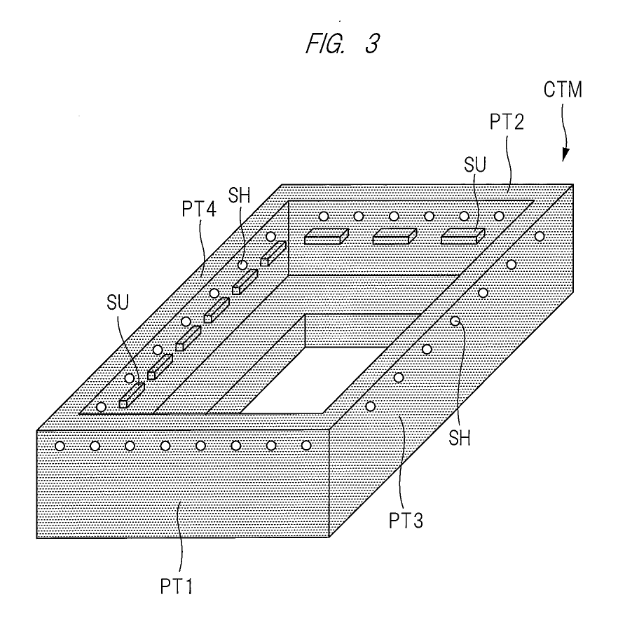

FIG. 3 is a schematic view showing a configuration aspect example of the deposition prevention member CTM according to the present embodiment. In the configuration aspect of the deposition prevention member CTM shown in FIG. 3, the parts P11 to P14 configuring the deposition prevention member CTM are formed to be unified. That is, the parts PT1 to PT4 of the deposition prevention member CTM shown in FIG. 3 are formed to be a seamless unified body. In this manner, according to the deposition prevention member CTM configured of the unified parts PT1 to PT4, the following advantages can be obtained.

That is, as described in the section <Space for Specific Improvement in Atomic Layer Deposition Apparatus>, the plasma atomic layer deposition apparatus has such characteristics as the formation of the film even in the portion where the plasma discharge is not generated because of being away from the discharge space and the formation of the film even in the small gap because of the film formation in the atomic layer unit. From these viewpoints, in the plasma atomic layer deposition apparatus, the film is adhered also on, for example, the deposition prevention member CTM covering the upper electrode. Regarding this point, the parts PT1 to PT4 of the deposition prevention member CTM shown in FIG. 3 are formed as the seamless unified body. Therefore, since the small gap is not formed in the deposition prevention member CTM shown in FIG. 3, the occurrence of the foreign substances due to the formation of the film in the small gap and the peeling off of the film therefrom can be suppressed in the deposition prevention member CTM. That is, in the plasma atomic layer deposition apparatus in which the film to be a source origin of the foreign substances is formed even in the corners of the film-forming container, it is desirable to use a member allowing the occurrence of the foreign substances to reduce as much as possible. From this viewpoint, it can be said that the deposition prevention member CTM that is formed as the seamless unified body is a desirable member from which the source origin of the foreign substances is removed as many as possible. This is because, when the deposition prevention member CTM is formed from the seamless unified body as shown in FIG. 3, there is essentially no small gap where the film is difficult to be removed, and therefore, a potential of the occurrence of the foreign substances due to the peeling of the film formed in the small gap can be eliminated. That is, according to the deposition prevention member CTM made of the seamless unified body, the deposition prevention member CTM that reduces the potential of the occurrence of the foreign substances because the member can be detached to remove the adhered film can be provided. As a result, by the deposition prevention member CTM made of the seamless unified body shown in FIG. 3, the foreign substances can be prevented from adhering onto the substrate, so that the film quality of the film formed on the substrate can be improved.

Further, the plasma atomic layer deposition apparatus has such characteristics as forming the film easier in the small gap than a flat surface. Therefore, according to the deposition prevention member CTM made of the seamless unified body, there is no small gap where the film is easily formed, and therefore, an advantage capable of providing a long maintenance cycle for the deposition prevention member CTM can be obtained.

<Second Configuration Aspect (Separation) of Deposition Prevention Member>

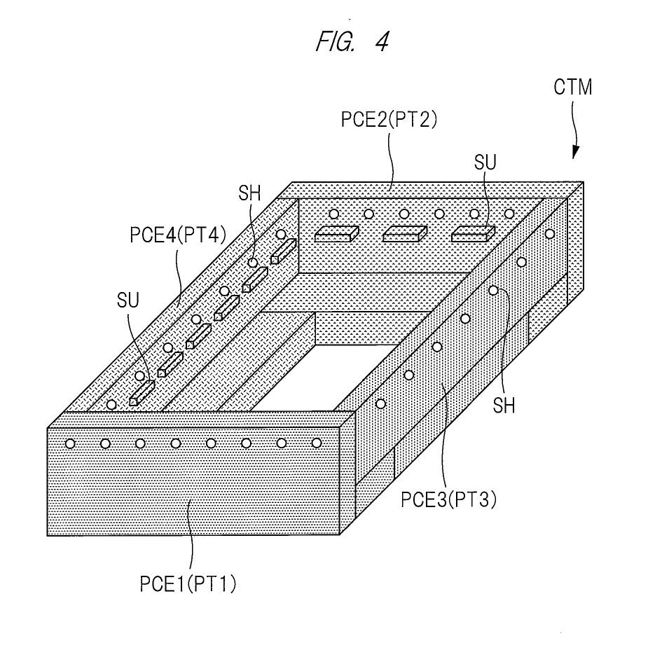

FIG. 4 is a schematic view showing another configuration aspect example of the deposition prevention member CTM according to the present embodiment. In the configuration aspect of the deposition prevention member CTM shown in FIG. 4, the parts PT1 to PT4 configuring the deposition prevention member CTM are configured of different pieces from one another. That is, the deposition prevention member CTM shown in FIG. 4 is configured of a piece PCE1 corresponding to the part PT1, a piece PCE2 corresponding to the part PT2, a piece PCE3 corresponding to the part PT3, and a piece PCE4 corresponding to the part PT4. As described above, the deposition prevention member CTM according to the present embodiment can be configured of not only the seamless unified body shown in FIG. 3 but also combination of different pieces shown in FIG. 4.

Here, since the deposition prevention member CTM shown in FIG. 4 is also configured of the combination of different pieces, the seams exist among the pieces. From this viewpoint, the deposition prevention member CTM shown in FIG. 4 has small gaps among the pieces, and the film is also formed in these small gaps. As a result, it is considered that the deposition prevention member CTM shown in FIG. 4 has a large potential of the occurrence of the foreign substances due to the peeling of the films formed in the small gaps.

Regarding this point, in the deposition prevention member CTM shown in FIG. 4, although the small gaps are formed, the potential of the occurrence of the foreign substances due to the peeling of the films formed in the small gaps can be reduced from the viewpoint of the configuration of the deposition prevention member CTM shown in FIG. 4 from the combination of the different pieces.

This viewpoint will be described below. When the deposition prevention member CTM is configured of the combination of the different pieces, it is surely considered that the potential of the occurrence of the foreign substances due to the peeling of the film formed in the small gaps becomes large since the small gap is formed among the pieces. However, practically, when the deposition prevention member CTM is configured of the combination of the different pieces, the deposition prevention member CTM can be dissolved into the pieces, and can be detached. When the deposition prevention member CTM is dissolved into the pieces as described above, there is no small gap caused when the pieces are combined with one another, and therefore, the film adhered on the portion corresponding to the small gap can be removed by the wet etching to the individual pieces. That is, when the deposition prevention member CTM is configured of the combination of the different pieces, although there is the small gap at the stage of the combination, the deposition prevention member CTM can be dissolved and detached. Therefore, by the wet etching performed to each of the dissolved pieces, even the film adhered on the part of the individual piece corresponding to the small gap can be sufficiently removed.

As described above, when the deposition prevention member CTM is configured of the combination of the different pieces, because of the dissolution after the detachment and because of the wet etching, the deposition prevention member CTM having the low potential of the occurrence of the foreign substances can be achieved. However, in this case, it is considered that, when the dissolved pieces are combined with one another again, an attachment shape and an attachment position of the deposition prevention member CTM before the dissolution and an attachment shape and an attachment position of the deposition prevention member CTM after the dissolution are slightly different from each other. However, the deposition prevention member CTM itself is not a part having the direct relevance to the plasma discharge as different from the upper electrode and the lower electrode. Therefore, even if the attachment shapes and the attachment positions of the deposition prevention member CTM before and after the dissolution are slightly different from each other, it is considered that this difference does not largely affect the typical film forming conditions in the plasma discharge. From this point, it is considered that, even if the deposition prevention member CTM is configured of the combination of the different pieces, there is almost no change in the film forming conditions that may be caused by the slight difference in the attachment shape and the attachment position. Even if there is the change in the film forming conditions that may be caused by the slight difference in the attachment shape and the attachment position of the piece, it is considered that the change is negligible. Therefore, even if the deposition prevention member CTM is configured of the combination of the different pieces as shown in FIG. 4, the deposition prevention member CTM is effective because the film adhered on the piece can be removed without the large change in the film forming conditions and because the potential of the occurrence of the foreign substances can be reduced to some extent. That is, while the deposition prevention member CTM configured of the seamless unified body shown in FIG. 3 is desirable from the viewpoint of the suppression of the occurrence of the foreign substances from the deposition prevention member CTM, the adhesion of the foreign substances on the substrate can be also prevented by the deposition prevention member CTM configured of the combination of the different pieces shown in FIG. 4. Therefore, the film quality of the film formed on the substrate can be improved.

However, as described above, the plasma atomic layer deposition apparatus has such characteristics as forming the film easier in the small gap than the flat surface. From this viewpoint, in the case of the deposition prevention member CTM configured of the combination of the different pieces, the potential of the occurrence of the foreign substances is larger by the existence of the small gap where the film is easily formed than that in the case of the deposition prevention member CTM configured of the seamless unified body. As a result, the maintenance cycle for the deposition prevention member CTM is shorter. That is, from the viewpoint of lengthening of the maintenance cycle, the case of the deposition prevention member CTM configured of the seamless unified body is more desirable than the case of the deposition prevention member CTM configured of the combination of the different pieces.

Meanwhile, as shown in FIG. 4, the case of the deposition prevention member CTM configured of the combination of the different pieces has a useful point capable of obtaining the following advantages. As a first advantage, because of the formation of the small gaps in the seams among the pieces, even if, for example, volume expansion of each piece of the deposition prevention member CTM is caused by the heating the inside of the film-forming container, this volume expansion can be absorbed by the small gaps among the pieces. As a result, deformation of the deposition prevention member CTM due to the heating of the inside of the film-forming container can be suppressed. This means that increase in the stress on a connecting portion between the deposition prevention member CTM and a fixing member that fixes the deposition prevention member CTM can be suppressed, and therefore, stability of the attachment of the deposition prevention member CTM can be improved.

Subsequently, as a second advantage, for example, even if a size of the deposition prevention member CTM surrounding the upper electrode increases in accordance with increase in a size of the upper electrode caused by large scaling of the plasma atomic layer deposition apparatus, manufacturing easiness of the deposition prevention member CTM can be secured since the deposition prevention member CTM is configured of the plurality of different pieces. This is because the deposition prevention member CTM is made of an insulator formed by, for example, processing of ceramic. In this case, when the deposition prevention member CTM is configured of the unified body, processing in a large size is required, and manufacturing difficulty is particularly large from the viewpoint of the processing of the ceramic. Regarding this point, when the deposition prevention member CTM is configured of the plurality of different pieces, a size of each of the plurality of pieces can be small, and therefore, processing easiness can be improved. That is, as shown in FIG. 4, when the deposition prevention member CTM is configured of the combination of the different pieces, the advantage capable of improving the manufacturing easiness of the deposition prevention member CTM itself can be obtained.

Further, regarding a third advantage, when the deposition prevention member CTM is configured of the unified body, a weight of the deposition prevention member CTM itself becomes large. As a result, a load on the attachment of the member to the plasma atomic layer deposition apparatus becomes large. On the other hand, when the deposition prevention member CTM is configured of the plurality of different pieces, handling of each of the pieces themselves becomes easier, and therefore, the attachment easiness and the maintenance workability of the deposition prevention member CTM can be improved. From the above-described viewpoints, the case of the deposition prevention member CTM configured of the combination of the different pieces as shown in FIG. 4 is useful because the manufacturing easiness of the deposition prevention member CTM itself can be improved and because the attachment easiness and the maintenance work easiness of the deposition prevention member CTM can be improved.

Note that the small gap formed in the seam among the pieces is desirable to have a value in a range that is, for example, equal to or larger than 0.001 mm and equal to or smaller than 20 mm. Particularly, it is desirable to determine the value of the small gap in comprehensive consideration of the viewpoint of prevention of the damage due to interference among the pieces on the basis of an attachment accuracy and the viewpoint of the suppression of the unnecessary film formation in the gap as much as possible.

<Detailed Configuration of Portion Supporting Upper Electrode>

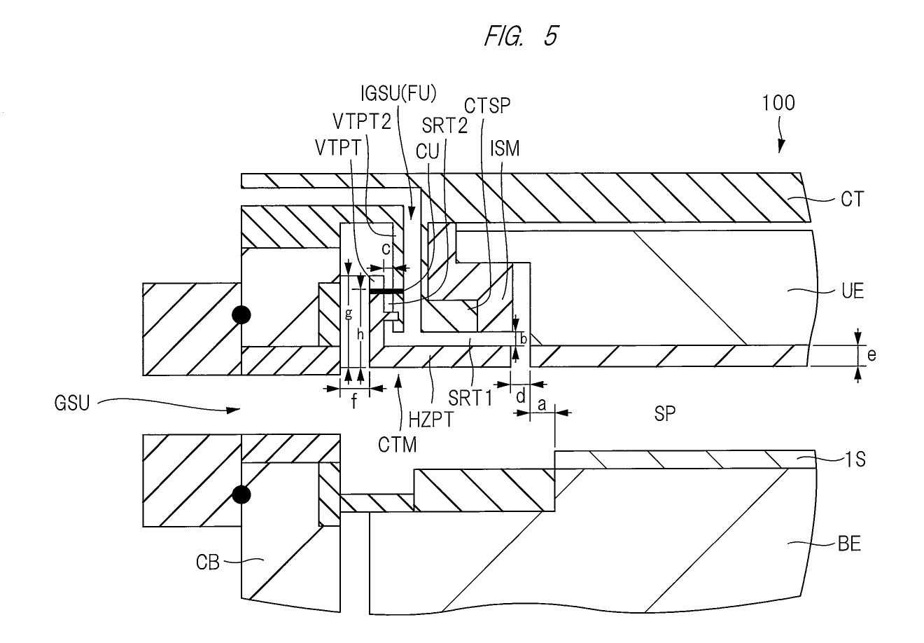

Next, a detailed configuration of a portion supporting the upper electrode will be described. FIG. 5 is a diagram schematically showing the detailed configuration of the portion supporting the upper electrode UE in FIG. 1. In FIG. 5, the insulating support member ISM is closely adhered to the top-plate support portion CTSP protruding from the top plate CT, and the upper electrode UE is supported by this insulating support member ISM. At this time, as shown in FIG. 5, while the upper electrode UE is supported by this insulating support member ISM in a vertical direction (up and down direction of FIG. 5), the gap is formed between the upper electrode UE and the insulating support member ISM in a part of a horizontal direction (right and left direction of FIG. 5). This is because the insulating support member ISM is made of the insulator typified by ceramic while the upper electrode UE is made of a conductor so that they are largely different from each other in a coefficient of thermal expansion. That is, when the upper electrode UE made of the conductor and the insulating support member ISM made of the insulator are closely adhered to each other in the entire horizontal direction, the upper electrode UE and the insulating support member ISM significantly deform because of the large difference between the coefficient of thermal expansion of the upper electrode UE and the coefficient of thermal expansion of the insulating support member ISM. In this case, it is considered that, for example, the deformation of the upper electrode UE changes the state (film forming conditions) of the plasma discharge. Accordingly, as shown in FIG. 5, in the present embodiment, the gap is formed between the upper electrode UE and the insulating support member ISM in a part of the horizontal direction (right and left direction of FIG. 5). The volume expansion of the upper electrode UE can be absorbed by the gap, so that the change of the state of the plasma discharge (change of the film forming conditions) due to the deformation of the upper electrode UE can be suppressed.

Subsequently, as shown in FIG. 5, the inert-gas supply portion IGSU supplying the inert gas into the film-forming container is arranged in the top plate CT, and this inert-gas supply portion IGSU is formed so as to be adjacent to the top-plate support portion CTSP. As shown in FIG. 5, the plasma atomic layer deposition apparatus 100 according to the present embodiment has the deposition prevention member CTM surrounding the upper electrode UE but being away therefrom in a plan view. At this time, in a plan view, the deposition prevention member CTM is arranged so as to overlap the insulating support member ISM, the top-plate support portion CTSP and the inert-gas supply portion IGSU. Here, the inert-gas supply portion IGSU is configured so as to supply the inert gas into the gap between the upper electrode UE and the deposition prevention member CTM. Between the deposition prevention member CTM and the inert-gas supply portion IGSU, an inert-gas supply channel through which the inert gas flows is formed. Specifically, as shown in FIG. 5, the inert-gas supply channel has an inert-gas supply channel SRT1 through which the inert gas flows in a direction toward the upper electrode UE and an inert-gas supply channel SRT2 through which the inert gas flows in a direction away from the upper electrode UE. Particularly, as shown in FIG. 5, the inert-gas supply channel SRT2 has a vertical flow channel through which the inert gas flows in the vertical direction (up and down direction of FIG. 5), and a vertical part VTPT of the deposition prevention member and a vertical part VTPT2 of the inert-gas supply portion IGSU sandwiching the vertical flow channel are connected to each other by a fixing member. That is, as shown in FIG. 5, the deposition prevention member CTM has an “L” shape having a horizontal part HZPT and the vertical part VTPT, and the vertical part VTPT of the deposition prevention member CTM and the vertical part VTPT2 of the inert-gas supply portion IGSU are connected to each other by the fixing member. In other words, the inert-gas supply portion IGSU functions as a fixing portion FU that fixes the deposition prevention member CTM, and a vertical part VTPT2 of this fixing portion FU and the vertical part VTPT of the deposition prevention member CTM are connected to each other at a connecting portion CU. As described above, the portion supporting the upper electrode UE is configured.

<Correspondence Relation Between Cross-sectional Configuration and Planar Configuration of Portion Supporting Upper Electrode>

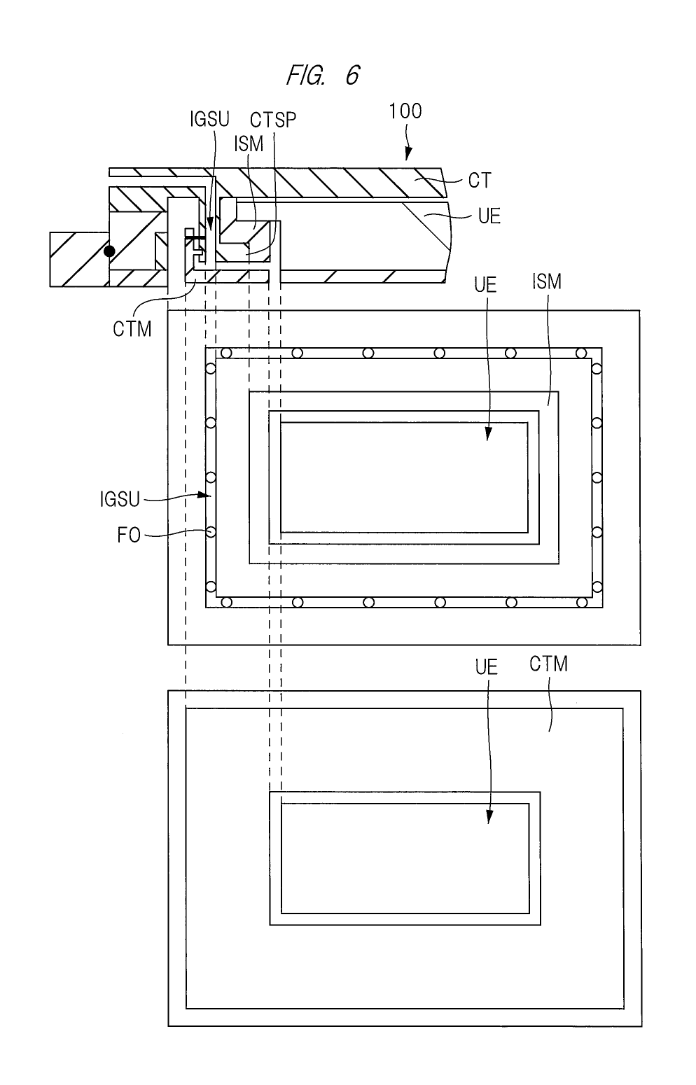

Next, a correspondence relation between a cross-sectional configuration and a planar configuration of the portion supporting the upper electrode will be described. FIG. 6 is diagrams schematically showing the correspondence relation between the cross-sectional configuration and the planar configuration of the portion supporting the upper electrode UE in the plasma atomic layer deposition apparatus 100. An upper diagram of FIG. 6 corresponds to a cross-sectional view, a center diagram of FIG. 6 corresponds to a plan view obtained when the deposition prevention member CTM is transparently viewed from a lower side, and a lower diagram of

FIG. 6 corresponds to a plan view obtained when the deposition prevention member CTM is viewed from the lower side so that the deposition prevention member is not eliminated.

In the center diagram of FIG. 6, the insulating support member ISM is arranged so as to surround the upper electrode UE having a rectangular shape but be away therefrom, and the inert-gas supply portion IGSU is arranged so as to surround this insulating support member ISM. A plurality of supply ports FO from which the inert gas is supplied are formed in this inert-gas supply portion IGSU. In the lower diagram of FIG. 6, the deposition prevention member CTM is arranged so as to surround the upper electrode UE but be away therefrom. Therefore, as seen in overlap between the center diagram of FIG. 6 and the lower diagram of FIG. 6, the deposition prevention member CTM is arranged so as to include the insulating support member ISM and the inert-gas supply portion IGSU therein in a plan view.

<Feature Point of Structure of Embodiment>

The plasma atomic layer deposition apparatus 100 according to the present embodiment is configured as described above, and feature points of the apparatus will be described below.

As a first feature point of the present embodiment, for example, the deposition prevention member CTM is arranged so as to surround the upper electrode UE in a plan view as shown in FIG. 2. Because of this point, the film can be prevented from adhering on a member arranged in periphery of the upper electrode UE. That is, the plasma atomic layer deposition apparatus has such characteristics as (1) the formation of the film in the atomic layer unit, (2) the spreading of the source gas and the reaction gas even to the corners of the film-forming container, and (3) the easiness of the reaction between the source gas and the reaction gas even in the portion where the plasma discharge is not generated, and therefore, the film is also adhered on a member arranged in a portion being away from the discharge space between the upper electrode UE and the lower electrode BE. Particularly, since a member arranged in periphery of the upper electrode UE is close to the discharge space, the film is easily adhered on the member. Therefore, in the present embodiment, in a plan view, the deposition prevention member CTM is arranged so as to surround the periphery of the upper electrode UE. In this manner, the film adhesion on the member arranged in periphery of the upper electrode UE can be effectively prevented.

Particularly, a technical significance of such arrangement of the deposition prevention member CTM as surrounding the periphery of the upper electrode UE is as follows. For example, when the deposition prevention member CTM is not arranged so as to overlap the member arranged in the periphery of the upper electrode UE in a plan view, the film is adhered on the member arranged in the periphery of the upper electrode UE. When a thickness of the film adhering on the member arranged in the periphery of the upper electrode UE is large, a part of the adhered film is peeled off and becomes foreign substances. Particularly, the member arranged in the periphery of the upper electrode UE is arranged close to the upper electrode UE arranged above the discharge space, and therefore, the foreign substances peeled off from the member arranged in the periphery of the upper electrode UE easily adhere on the substrate 1S loaded on the lower electrode BE below the discharge space. This case has a risk of deterioration of the film quality of the film formed on the substrate 1S due to the foreign substances. That is, in order to improve the film quality of the film formed on the substrate 1S, it is important to suppress the adhesion of the foreign substances onto the substrate 1S, the foreign substances being caused from the member arranged in the periphery of the upper electrode UE. That is, the member arranged in the periphery of the upper electrode UE is arranged close to the upper electrode UE, and this means that the member arranged in the periphery of the upper electrode UE is arranged so as to be close to and be above the substrate 1S loaded on the lower electrode BE in a plan view. As a result, by the foreign substances caused by the peeling of the film adhered on the member arranged in the periphery of the upper electrode UE, the film quality of the film formed on the substrate 1S is significantly affected. Therefore, in order to improve the film quality of the film formed on the substrate 1S, it is important to prevent the adhesion of the film onto the member arranged in the periphery of the upper electrode UE. In order to achieve the prevention, in the present embodiment, the deposition prevention member CTM is arranged so as to surround the upper electrode UE in a plan view. That is, the first feature point of the present embodiment has the technical significance that is the prevention of the film adhesion on the member arranged in the periphery of the upper electrode UE, so that the deterioration of the film quality of the film formed on the substrate 1S can be suppressed.

Here, according to the first feature point of the present embodiment, while the film adhesion on the member arranged in the periphery of the upper electrode UE is prevented, the film is adhered on the deposition prevention member CTM arranged so as to surround the upper electrode UE. Therefore, a part of the film adhered on the deposition prevention member CTM possibly peels off and becomes the foreign substances. However, the deposition prevention member CTM is configured so as to be detachable. Therefore, for example, when the thickness of the film adhered on the deposition prevention member CTM reaches a predetermined thickness, such a maintenance work as removing the film adhered on the deposition prevention member CTM by the wet etching after the deposition prevention member CTM is detached, and then, attaching the deposition prevention member CTM from which the film has been removed again is performed, so that the occurrence of the foreign substances from the deposition prevention member CTM can be suppressed.

Regarding this, it is considered that the film adhered on the deposition prevention member CTM is removed by the wet etching after the member arranged in the periphery of the upper electrode UE is detached, and then, the deposition prevention member CTM from which the film has been removed is attached again. This case is also considered so that the occurrence of the foreign substances from the member arranged in the periphery of the upper electrode UE can be suppressed.

However, this case causes the following adverse effect. Regarding this, as shown in, for example, FIG. 5, the insulating support member ISM that supports the upper electrode UE will be described as one example of the member arranged in the periphery of the upper electrode UE. As shown in FIG. 5, the upper electrode UE is supported by the insulating support member ISM. From this viewpoint, a method is considered in order to, for example, remove the film adhered on the insulating support member ISM, the method detaching the insulating support member ISM that fixes the upper electrode UE and removing the film adhered on the insulating support member ISM by the wet etching. However, when the insulating support member ISM is attached again after the insulating support member ISM is detached and the wet etching is performed, an attachment position of the upper electrode UE is different from a previous attachment position thereof. In this case, the state of the plasma discharge between the upper electrode UE and the lower electrode BE changes. In the method of detaching the insulating support member ISM and cleaning the insulating support member by the wet etching, the attachment position of the insulating support member ISM cannot be reproduced. As a result, this causes an adverse effect of the change of the attachment position of the upper electrode UE supported by the insulating support member ISM, which results in change of the typical film forming conditions in the state of the plasma discharge. This case has a risk of the change in the film quality of the film formed on the substrate.

On the other hand, in the present embodiment, for example, as shown in FIG. 5, the insulating support member ISM that supports the upper electrode UE is arranged in the periphery of the upper electrode UE, and the deposition prevention member CTM is arranged so as to surround the upper electrode UE in order to prevent the film adhesion on this insulating support member ISM. Specifically, as shown in FIG. 6, the deposition prevention member CTM is arranged so as to overlap the insulating support member ISM in a plan view. In this manner, according to the present embodiment, the film adhesion on the insulating support member ISM can be prevented. As a result, it is not required to detach the insulating support member ISM. Therefore, according to the present embodiment, it is not required to attach the insulating support member ISM again after the insulating support member ISM is detached and the wet etching is performed, so that the adverse effect that is the change of the film forming conditions due to the difference between the attachment position of the upper electrode UE and the previous attachment position thereof can be prevented.

Meanwhile, regarding the deposition prevention member CTM in the present embodiment, the film adhered on the deposition prevention member CTM is removed by the wet etching or others after the deposition prevention member CTM is detached, and then, the deposition prevention member CTM from which the film has been removed is attached again. Regarding this, even if the film adhered on the deposition prevention member CTM is removed after the deposition prevention member CTM is detached, and then, the deposition prevention member CTM from which the film has been removed is attached again, the attachment position of the upper electrode UE and the previous attachment position thereof are not different from each other since, for example, the deposition prevention member CTM is not the member that supports the upper electrode UE as shown in FIG. 5. That is, even if the film adhered on the deposition prevention member CTM is removed after the deposition prevention member CTM is detached, and then, the deposition prevention member CTM from which the film has been removed is attached again, the adverse effect that is the change of the film forming conditions due to the difference between the attachment position of the upper electrode UE and the previous attachment position thereof is not caused. From this viewpoint, according to the first feature point of the present embodiment, a significant effect capable of improving the quality of the film formed on the substrate without the change of the film forming conditions can be obtained.

Next, as a second feature point of the present embodiment, for example, the deposition prevention member CTM is arranged so as to surround the upper electrode UE but being away therefrom as shown in FIGS. 2 and 5. In this manner, deformation and damage of each of the upper electrode UE and the deposition prevention member CTM can be prevented. For example, while the upper electrode UE is made of the conductor, the deposition prevention member CTM is made of the insulator (ceramic). Therefore, the coefficient of thermal expansion of the upper electrode UE and the coefficient of thermal expansion of the deposition prevention member CTM are significantly different from each other. In this case, for example, when the deposition prevention member CTM is formed so as to surround the upper electrode UE and being closely adhering thereto, there is a risk of occurrence of distortion and deformation in each of the upper electrode UE and the deposition prevention member CTM because of the difference between the coefficient of thermal expansion of the upper electrode UE and the coefficient of thermal expansion of the deposition prevention member CTM. When the distortion is large, there is a risk of damage particularly on the deposition prevention member CTM made of the ceramic. Therefore, in the present embodiment, the deposition prevention member CTM is arranged so as to, for example, surround the upper electrode UE but being away therefrom as shown in FIG. 5. In other words, the gap is formed between the upper electrode UE and the deposition prevention member CTM. In this manner, because of the second feature point of the present embodiment, the volume expansion of each of the upper electrode UE and the deposition prevention member CTM is absorbed by the gap even if the inside of the film-forming container is heated, and therefore, the deformation of and the damage on the upper electrode UE and the deposition prevention member CTM can be suppressed.

However, when the second feature point according to the present embodiment is achieved, the gap is essentially formed between the upper electrode UE and the deposition prevention member CTM as shown in FIG. 5. In this case, the gap is undesirably formed between the upper electrode UE and the deposition prevention member CTM because of such characteristics of the plasma atomic layer deposition apparatus as forming the film even in the corners inside the film-forming containers including the small gap. Particularly, in order to prevent the deformation and the damage due to the difference in the coefficient of thermal expansion as shown in FIG. 5, the gap is also formed between a part of the insulating support member ISM and the upper electrode UE because of the same reason for the formation of the gap between the upper electrode UE and the deposition prevention member CTM. Therefore, there is the concern that the film is undesirably formed in the part of the insulating support member ISM exposed from the gaps when the source gas and the reaction gas infiltrate into these gaps. That is, when such a first feature point as forming the deposition prevention member CTM so as to surround the upper electrode UE in a plan view is embodied, if such a second feature point as forming the deposition prevention member CTM so as to surround the upper electrode UE “but be away therefrom” is applied in consideration of the difference in the coefficient of thermal expansion among the members, the unnecessary film possibly adheres on, for example, the part of the insulating support member ISM supporting the upper electrode UE. That is, from the viewpoint of the achievement of maintenance free for the insulating support member ISM by nearly-complete prevention of the adhesion of the film onto the insulating support member ISM supporting the upper electrode UE, the configuration having the second feature point is not sufficient, and therefore, development for further improvement is required. Accordingly, in the present embodiment, the development for the nearly-complete prevention of the adhesion of the film onto the part of the insulating support member ISM supporting the upper electrode UE has been made while the configuration having the second feature point is applied. This development point is a third feature point of the present embodiment. The third feature point of the present embodiment will be described below.

As the third feature point of the present embodiment, for example, the inert-gas supply portion IGSU that supplies the inert gas into the gap between the upper electrode UE and the deposition prevention member CTM is arranged as shown in FIG. 5. Specifically, as shown in FIG. 5, the inert-gas supply portion IGSU that is formed by processing the top plate CT is arranged outside the top-plate support portion CTSP that fixes the insulating support member ISM supporting the upper electrode UE. The inert-gas supply portion IGSU is connected to an inert-gas supply channel SRT1 made of the gap between the deposition prevention member CTM and the top-plate support portion CTSP and the gap between the deposition prevention member CTM and the insulating support member ISM. This inert-gas supply channel SRT1 functions as a channel through which the inert gas that is supplied from the inert-gas supply portion IGSU flows in a direction toward the upper electrode UE, and is connected to the gap between the deposition prevention member CTM and the upper electrode UE and the gap between the insulating support member ISM and the upper electrode UE.

In this manner, according to the third feature point of the present embodiment, the inert gas that is supplied from the inert-gas supply portion IGSU flows through the inert-gas supply channel SRT1, and fills the gap between the deposition prevention member CTM and the upper electrode UE and the gap between the insulating support member ISM and the upper electrode UE. Therefore, even if the gaps between the deposition prevention member CTM and the upper electrode UE and between the part of the insulating support member ISM and the upper electrode UE are formed as a result of the application of the second feature point of the present embodiment, the inert gas fills these gaps. In other words, by the inert gas supplied from the inert-gas supply portion IGSU, the source gas and the reaction gas is prevented from infiltrating into the gaps between the deposition prevention member CTM and the upper electrode UE and between the part of the insulating support member ISM and the upper electrode UE. As a result, even if the gap is formed between the part of the insulating support member ISM and the upper electrode UE, the source gas and the reaction gas can be prevented from infiltrating into this gap, and therefore, the film is prevented from adhering on the part of the insulating support member ISM exposed from this gap.

From the above description, according to the third feature point of the present embodiment, even if such a second feature point of the present embodiment as forming the deposition prevention member CTM so as to surround the upper electrode UE “but be away therefrom” is applied in consideration of the difference in the coefficient of thermal expansion among the members, for example, the unnecessary film can be prevented from adhering onto the part of the insulating support member ISM supporting the upper electrode UE. That is, by the application of both the second feature point and the third feature point of the present embodiment, the film can be nearly completely prevented from adhering onto the insulating support member ISM supporting the upper electrode UE while the potentials of the deformation of and the damage on the members are reduced. This means that the maintenance free for the insulating support member ISM can be nearly completely achieved by the application of both the second feature point and the third feature point of the present embodiment. As a result, a significant effect capable of improving the quality of the film formed on the substrate can be obtained without such an adverse effect as the change of the film forming conditions due to the difference between the attachment position of the upper electrode UE and the previous attachment position thereof.

Next, a fourth feature point of the present embodiment will be described. For example, in FIG. 5, a fixing method for the deposition prevention member CTM is considered so that the deposition prevention member CTM is fixed to the top-plate support portion CTSP by fixing the top-plate support portion CTSP and the deposition prevention member CTM sandwiching the inert-gas supply channel SRT1 by using a fixing member (screw). However, the inert-gas supply channel SRT1 sandwiched by the top-plate support portion CTSP and the deposition prevention member CTM is arranged at a position close to the discharge space. Therefore, if the supply of the inert gas from the inert-gas supply portion IGSU is insufficient, it is considered that the source gas and the reaction gas (active species) easily infiltrate the inert-gas supply channel SRT1. At this time, for example, a screw hole is formed in both the top-plate support portion CTSP and the deposition prevention member CTM, and they are fixed by using a screw (fixing member). However, in the plasma atomic layer deposition apparatus, the film is also adhered on a small gap of the screw hold, and therefore, the screw is strongly fixed by the film adhered on the screw hole. From this viewpoint, when the film is adhered on the screw hole, large force is required for detachment of the screw, and therefore, there is a risk of damage on the screw itself and the deposition prevention member CTM due to the force.

Therefore, in order to prevent the damage on the screw itself and the deposition prevention member CTM, the deposition prevention member CTM is desirably fixed at a portion that is away from the discharge space as far as possible. This is because, when the fixing portion for fixing the deposition prevention member CTM is formed at the portion that is away from the discharge space, the source gas and the reaction gas (active species) are difficult to reach the fixing portion for the deposition prevention member CTM even if the supply of the inert gas from the inert-gas supply portion IGSU is insufficient. That is, when the source gas and the reaction gas (active species) are difficult to reach the fixing portion for the deposition prevention member CTM, the film is difficult to adhere on the small gap of the screw hole, so that the strong fixing of the screw can be suppressed. As a result, the damage on the screw itself and the deposition prevention member CTM can be prevented.

In the present embodiment, such development as forming the fixing portion for fixing the deposition prevention member CTM at the portion that is away from the discharge space as far as possible has been made, and this development point is a fourth feature point of the present embodiment. That is, for example, as shown in FIG. 5, the fourth feature point of the present embodiment is made on the assumption that a shape of the deposition prevention member CTM is formed to an “L” shape having a horizontal part HZPT and a vertical part VTPT, so that an inert-gas supply channel SRT2 through which the inert gas flows in a direction away from the upper electrode UE is formed. As the fourth feature point of the present embodiment, formation of a vertical flow channel in the inert-gas supply channel SRT2 on the basis of the assumption configuration is utilized so that a connecting portion CU that connects the deposition prevention member CTM with the inert-gas supply portion IGSU is formed in this vertical flow channel. As the specific fourth feature point of the present embodiment, for example, a screw hole is formed in both the vertical part VTPT of the deposition prevention member CTM and the vertical part VTPT2 of the inert-gas supply portion IGSU, and the connecting portion CU that is fixed by the screw is formed.

In this manner, according to the fourth feature point of the present embodiment, the fixing portion (connecting portion) that fixes the deposition prevention member CTM is formed at the portion that is away from the discharge space as far as possible. As a result, for example, even if the supply of the inert gas from the inert-gas supply portion IGSU is insufficient, the source gas and the reaction gas (active species) can be difficult to reach the fixing portion (connecting portion) for the deposition prevention member CTM, so that the film is difficult to adhere on the small gap of the screw hole. Therefore, according to the fourth feature point of the present embodiment, the screw can be suppressed from being strongly fixed, and thus, the damage on the screw itself and the deposition prevention member CTM can be prevented.

For example, as shown in FIG. 2, note that not only the fixing hole (screw hole) SH but also a convex portion SU may be formed in the vertical part of the deposition prevention member CTM. In this manner, the vertical part of the deposition prevention member CTM and the vertical part of the inert-gas supply portion are connected to each other by both fixing means of inserting the screw into the fixing hole SH and fixing means using the convex portion SU, so that reliability of the connection between the deposition prevention member CTM and the inert-gas supply portion IGSU can be improved.

Next, as a fifth feature point of the present embodiment, for example, as shown in FIG. 5, the inert-gas supply portion IGSU that supplies the inert gas is arranged separately from the gas supply portion GSU that supplies the source gas and the reaction gas into the film-forming container. In this manner, particularly, regardless of the arrangement position of the gas supply portion GSU, a position at which the inert-gas supply portion IGSU is arranged can be designed so that the inert gas is effectively supplied to the portion where it is desirable to prevent the adhesion of the unnecessary film. Further, since the inert gas can be supplied through a channel that is different from that of the gas supply portion GSU supplying the source gas and the reaction gas, adverse influence of the flow of the inert gas on the flows of the source gas and the reaction gas supplied to the discharge space SP can be suppressed. As a result, according to the fifth feature point of the present embodiment, reduction in evenness of the source gas and the reaction gas on the substrate 1S due to the supply of the inert gas into the film-forming container can be suppressed, so that reduction in evenness of the film formed on the substrate 1S can be prevented while the inert gas is supplied.

<Specific Numerical Value Examples>

Next, in the plasma atomic layer deposition apparatus according to the present embodiment, features of the present embodiment and relative specific dimension examples will be described with reference to FIG. 5.

First, in a plan view, a distance “a” between an outer circumferential edge surface of the substrate 1S and an outer circumferential edge surface of the upper electrode is desirably equal to or larger than 0.1 mm, and is, for example, 50 mm in the plasma atomic layer deposition apparatus 100 according to the present embodiment. When the distance “a” is too small, the flows of the source gas and the reaction gas supplied onto the substrate 1S are easily affected by the flow of the inert gas, and therefore, there is a risk of the reduction in the evenness of the source gas and the reaction gas on the substrate 1S. On the other hand, when the distance “a” is too large, an apparatus size of the plasma atomic layer deposition apparatus 100 becomes large, and therefore, the distance has a desirable allowable range.

Subsequently, each of a distance “b” indicating a radius of the inert-gas supply channel SRT1 and a distance “c” indicating a radius of the inert-gas supply channel SRT2 can be set to be, for example, equal to or smaller than 20 mm. If an inner surface of the deposition prevention member CTM is made of a rough surface (for example, Ra (arithmetic average roughness)=3 μm to 6 μm), each of the distance “b” and the distance “c” can be set to almost zero. This is because, even if each of the distance “b” and the distance “c” is almost zero in this case, the channel through which the inert gas flows can be secured since the inner surface of the deposition prevention member CTM has a rough surface shape.

Next, a distance “d” between the deposition prevention member formed in a lower surface of the upper electrode UE and the deposition prevention member CTM is desirably in a range that is equal to or larger than 0.1 mm and equal to or smaller than 20 mm, and is, for example, 2 mm in the plasma atomic layer deposition apparatus 100 according to the present embodiment. By such a small distance “d”, the film can be prevented from adhering on the insulating support member ISM and the top-plate support portion CTSP due to the infiltration of the source gas and the reaction gas into the inert-gas supply channel SRT1.

Subsequently, a distance “e” that is a thickness of the deposition prevention member CTM or a thickness of the deposition prevention member formed in the lower surface of the upper electrode UE is desirably equal to or larger than 2 mm and equal to or smaller than 100 mm, and is, for example, 10 mm in the plasma atomic layer deposition apparatus 100 according to the present embodiment. By increase in the distance “e”, the film can be prevented from adhering on the insulating support member ISM and the top-plate support portion CTSP due to the infiltration of the source gas and the reaction gas into the inert-gas supply channel SRT1. However, when the distance “e” is too large, for example, a weight of the deposition prevention member CTM or a weight of the deposition prevention member formed in the lower surface of the upper electrode UE become large, and therefore, the maintenance workability is reduced, and thus, the distance has a desirable allowable range.

Next, a distance “f” between the deposition prevention member CTM and the gas supply portion GSU is desirably in a range that is equal to or larger than 0.1 mm and equal to or smaller than 50 mm, and is, for example, 10 mm in the plasma atomic layer deposition apparatus 100 according to the present embodiment. By such a small distance “f”, the source gas and the reaction gas can be prevented from infiltrating the inert-gas supply channel SRT2. However, when the distance “f” is too small, in the attachment/detachment between the top plate CT and the film-forming container at the time of the maintenance work, contact between the film-forming container and the deposition prevention member CTM is made to cause a risk of the damage on the deposition prevention member CTM, and therefore, the distance has a desirable allowable range.

Subsequently, a distance “g” indicating a length of the vertical part VTPT of the deposition prevention member CTM is desirably in a range that is equal to or larger than 2 mm and equal to or smaller than 200 mm, and is, for example, 50 mm in the plasma atomic layer deposition apparatus 100 according to the present embodiment. By such a large distance “g”, the source gas and the reaction gas can be prevented from infiltrating the inert-gas supply channel SRT2.

A distance “h” from the bottom surface of the deposition prevention member CTM to the attachment position of the connecting portion CU is desirably in a range that is equal to or larger than 2 mm and equal to or smaller than 200 mm, and is, for example, 40 mm in the plasma atomic layer deposition apparatus 100 according to the present embodiment. By such a large distance “h”, the film can be prevented from adhering on the connecting portion due to the infiltration of the source gas and the reaction gas into the inert-gas supply channel SRT2.

<Atomic Layer Deposition Method>

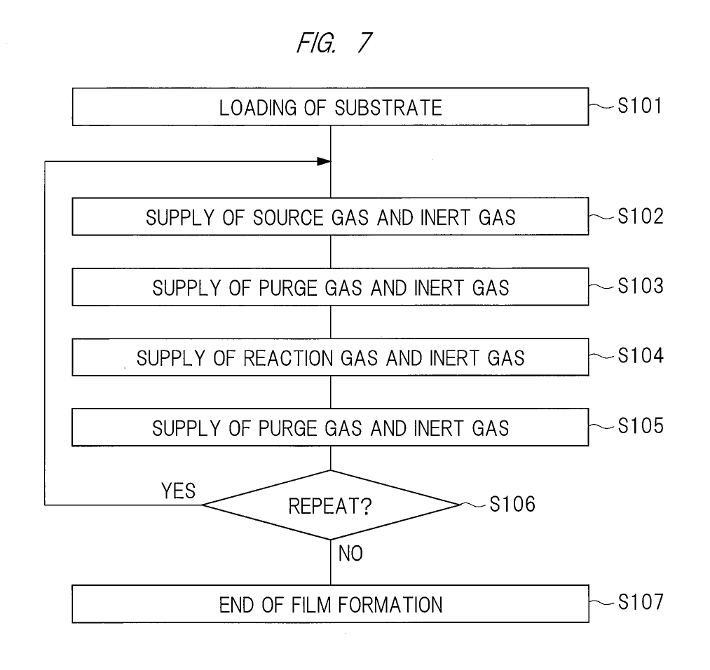

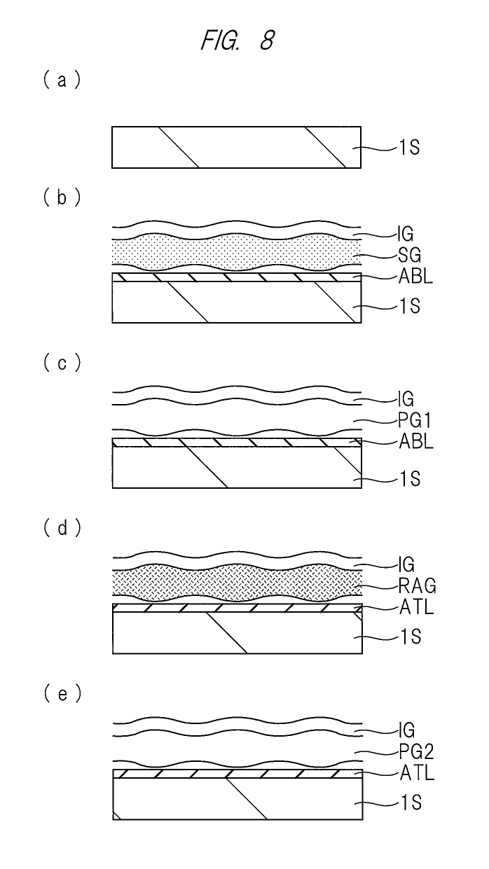

Next, an atomic layer deposition method according to the present embodiment will be described. FIG. 7 is a flowchart explaining the atomic layer deposition method according to the present embodiment, and FIG. 8(a) to (e) are diagrams each schematically showing a step of forming the film on the substrate.

First, after the substrate 1S shown in FIG. 8(a) is prepared, the substrate 1S is loaded on the lower electrode BE (stage) of the plasma atomic layer deposition apparatus 100 shown in FIG. 5 (S101 of FIG. 7). Subsequently, the source gas is supplied from the gas supply portion GSU of the plasma atomic layer deposition apparatus 100 shown in FIG. 5 into the film-forming container, and the inert gas is supplied from the inert-gas supply portion IGSU to the inert-gas supply channel SRT1 and the inert-gas supply channel SRT2 (S102 of FIG. 7). At this time, the source gas is supplied into the film-forming container for, for example, 0.1 second. In this manner, as shown in FIG. 8(b), the inert gas IG and the source gas SG are supplied into the film-forming container, and the source gas SG is adsorbed on the substrate 1S to form an adsorbed layer ABL.

Subsequently, after the supply of the source gas stops, the purge gas is supplied from the gas supply portion GSU, and the inert gas is supplied from the inert-gas supply portion IGSU to the inert-gas supply channel SRT1 and the inert-gas supply channel SRT2 (S103 of FIG. 7). In this manner, while the purge gas is supplied into the film-forming container, the source gas is exhausted from the outlet to outside of the film-forming container. The purge gas is supplied into the film-forming container for, for example, 0.1 second. From the outlet, the source gas and the purge gas in the film-forming container are exhausted for, for example, 2 seconds. In this manner, as shown in FIG. 8(c), the inert gas IG and the purge gas PG1 are supplied into the film-forming container, and the source gas SG not absorbed on the substrate 1S is purged from the film-forming container.

Next, the reaction gas is supplied from the gas supply portion GSU, and the inert gas is supplied from the inert-gas supply portion IGSU to the inert-gas supply channel SRT1 and the inert-gas supply channel SRT2 (S104 of FIG. 7). In this manner, the reaction gas is supplied into the film-forming container. The reaction gas is supplied into the film-forming container for, for example, 1 second. In this step of supplying the reaction gas, the plasma discharge is generated by application of a discharge voltage to a portion between the upper electrode UE and the lower electrode BE shown in FIG. 5. As a result, the radicals (active species) are generated in the reaction gas. In this manner as shown in FIG. 8(d), the inert gas IG and the reaction gas RAG are supplied into the film-forming container, and the adsorbed layer adsorbed on the substrate 1S and the reaction gas RAG chemically react with each other, so that a thin layer made of an atomic layer ATL is formed.

Subsequently, after the supply of the reaction gas stops, the purge gas is supplied from the gas supply portion GSU, and the inert gas is supplied from the inert-gas supply portion IGSU to the inert-gas supply channel SRT1 and the inert-gas supply channel SRT2 (S105 of FIG. 7). In this manner, while the purge gas is supplied into the film-forming container, the reaction gas is exhausted from the outlet to the outside of the film-forming container. The reaction gas is supplied into the film-forming container for, for example, 0.1 second. From the outlet, the source gas and the purge gas in the film-forming container are exhausted for, for example, 2 seconds. In this manner, as shown in FIG. 8(e), the inert gas IG and the purge gas PG2 are supplied into the film-forming container, and the excess reaction gas RAG not used for the reaction is purged from the film-forming container.

In the manner as described above, the thin layer made of one atomic layer ATL is formed on the substrate 1S. Then, thin layers made of a plurality of atomic layers ATL are formed by predetermined-number repetitions (S106 of FIG. 7) of the above-described steps (S102 of FIG. 7 to S105 of FIG. 7). Then, the film-forming process ends (S107 of FIG. 7).

<Manufacturing Feature of Embodiment>

In the atomic layer deposition method according to the present embodiment, the film is formed on the substrate by using the plasma. Here, the atomic layer deposition method according to the present embodiment includes (a) a step of supplying the source gas into the film-forming container in which the substrate is arranged, (b) after the step (a), a step of supplying a first purge gas into the film-forming container, (c) after the step (b), a step of supplying the reaction gas into the film-forming container, and (d) after the step (c), a step of supplying a second purge gas into the film-forming container. As a manufacturing feature point of the present embodiment, the inert gas is further supplied into the film-forming container through the step (a), the step (b), the step (c) and the step (d).

This manner can obtain such an advantage as making it difficult to form the unnecessary film becoming the source origin of the foreign substances in the film-forming container. Particularly in the plasma atomic layer deposition apparatus shown in FIG. 5 embodying the atomic layer deposition method according to the present embodiment, while the source gas, the purge gas and the reaction gas are supplied from the gas supply portion GSU, the inert gas is supplied from the inert-gas supply portion IGSU that is difference from the gas supply portion GSU. In this manner, regardless of the arrangement position of the gas supply portion GSU, the inert gas can be effectively supplied to the portion on which it is desirable to prevent the adhesion of the unnecessary film (the portion significantly affecting the film quality of the film formed on the substrate 1S). From the viewpoint, according to the present embodiment, the film quality of the film formed on the substrate 1S can be improved.

Further, according to the atomic layer deposition method of the present embodiment, pressure variation in the film-forming container through the step (a), the step (b), the step (c) and the step (d) can be set to be smaller than pressure variation in the film-forming container in the case without the supply of the inert gas. This is because difference among a flow rate of the source gas, a flow rate of the purge gas and a flow rate of the reaction gas is moderated by a flow rate of the inert gas supplied into the film-forming container through the step (a), the step (b), the step (c) and the step (d). That is, in the present embodiment, the flow rate of the inert gas supplied into the film-forming container through the step (a), the step (b), the step (c) and the step (d) is adjusted so that a flow rate of combination of the source gas and the inert gas, a flow rate of combination of the purge gas and the inert gas and a flow rate of combination of the reaction gas and the inert gas are equal to one another. As a result, according to the atomic layer deposition method of the present embodiment, the pressure variation in the film-forming container through the step (a), the step (b), the step (c) and the step (d) is smaller than the pressure variation in the film-forming container in the case without the supply of the inert gas. In this manner, the occurrence of the foreign substances due to the pressure variation in the film-forming container can be suppressed. This is because the atomic layer deposition method causes the film adhesion on the portion where the adhesion is not required in the film-forming container, which results in the foreign substances by the peeling of a part of the adhered film, and the film is oscillated by the pressure variation when the pressure variation in the film-forming container is large, which results in advancement of the film peeling. In other words, since the pressure variation in the film-forming container can be small in the present embodiment, the advancement of the film peeling to be the cause of the occurrence of the foreign substances can be suppressed. Therefore, according to the manufacturing feature point of the present embodiment, the occurrence of the foreign substances can be suppressed, and thus, the reduction in the film quality of the film formed on the substrate due to the occurrence of the foreign substances can be suppressed.

<Application Example of Atomic Layer Deposition Method>

In the atomic layer deposition method according to the present embodiment, an aluminum oxide film can be formed by using, for example, TMA as the source gas, oxygen gas as the reaction gas, and nitrogen gas as the purge gas. Particularly, the aluminum oxide film formed on the substrate can be formed as a film forming a part of a protective film that protects a light emitting layer of an organic EL element.

As the film formed on the substrate, not the aluminum oxide film but various films typified by a silicon oxide film may be used. For example, the film formed on the substrate by the atomic layer deposition method according to the present embodiment can be also formed as a film forming a gate insulating film of a field effect transistor (semiconductor element).

In the foregoing, the invention made by the present inventors has been concretely described on the basis of the embodiment. However, it is needless to say that the present invention is not limited to the foregoing embodiment, and various modifications and alterations can be made within the scope of the present invention.

For example, in the above-described embodiment, the configuration in which the substrate is loaded on the lower electrode and in which the deposition prevention member is formed so as to surround the upper electrode facing the lower electrode has been described. However, the technical concept according to the above-described embodiment is not limited to this, but also applied to a configuration in which the substrate is supported on the upper electrode and in which the deposition prevention member is formed so as to surround the lower electrode facing the upper electrode.

### EXPLANATION OF REFERENCE CHARACTERS

100 plasma atomic layer deposition apparatus, BE lower electrode, CTM deposition prevention member, CU connecting portion, FU fixing portion, GSU gas supply portion, HZPT horizontal portion, IGSU inert-gas supply portion, ISM insulating support member, PCE1 piece, PG2 piece, PCE3 piece, PCE4 piece, PT1 part, PT2 part, PT3 part, PT4 part, SRT1 inert-gas supply channel, SRT2 inert-gas supply channel, SS1 side surface, SS2 side surface, SS3 side surface, SS4 side surface, SUR surface, UE upper electrode, VTPT vertical part, VTPT2 vertical part

1. A plasma atomic layer deposition apparatus forming a film on a substrate, comprising:
a first electrode configured to hold the substrate;
a second electrode facing the first electrode and configured to generate plasma discharge between the second electrode and the first electrode; and
a deposition prevention member made of an insulator surrounding the second electrode but being away therefrom in a plan view.

2. The plasma atomic layer deposition apparatus according to claim 1,
wherein the plasma atomic layer deposition apparatus further has an insulating support member configured to support the second electrode, and
the deposition prevention member is arranged so as to overlap the insulating support member in a plan view.

3. The plasma atomic layer deposition apparatus according to claim 1,
wherein the second electrode has:
a surface facing the first electrode;
a first side surface crossing the surface;
a second side surface positioned on an opposite side of the first side surface;
a third side surface crossing the surface and the first side surface; and
a fourth side surface positioned on an opposite side of the third side surface,
the deposition prevention member has:
a first part facing the first side surface of the second electrode;
a second part facing the second side surface of the second electrode;
a third part facing the third side surface of the second electrode; and
a fourth art facing the fourth side surface of the second electrode, and
the surface of the second electrode is exposed from the deposition prevention member.

4. The plasma atomic layer deposition apparatus according to claim 3,
wherein the first part, the second part, the third part and the fourth part are unified.

5. The plasma atomic layer deposition apparatus according to claim 3,
wherein the deposition prevention member includes:
a first piece corresponding to the first part;
a second piece corresponding to the second part;
a third piece corresponding to the third part; and
a fourth piece corresponding to the fourth part.

6. The plasma atomic layer deposition apparatus according to claim 3,
wherein the first part has an L shape having a first horizontal part and a first vertical part,
the second part has an L shape having a second horizontal part and a second vertical part,
the third part has an L shape having a third horizontal part and a third vertical part, and
the fourth part has an L shape having a fourth horizontal part and a fourth vertical part.

7. The plasma atomic layer deposition apparatus according to claim 6,
wherein the plasma atomic layer deposition apparatus further has a fixing portion configured to fix the deposition prevention member, and
the deposition prevention member and the fixing portion are connected to each other by a first connecting portion for the first vertical part and the fixing portion, a second connecting portion for the second vertical part and the fixing portion, a third connecting portion for the third vertical part and the fixing portion, and a fourth connecting portion for the fourth vertical part and the fixing portion.

8. The plasma atomic layer deposition apparatus according to claim 1,
wherein the plasma atomic layer deposition apparatus further has an inert-gas supply portion configured to supply inert gas to a gap between the second electrode and the deposition prevention member.

9. The plasma atomic layer deposition apparatus according to claim 8,
wherein the deposition prevention member is fixed to the inert-gas supply portion.

10. The plasma atomic layer deposition apparatus according to claim 8,
wherein the deposition prevention member is arranged so as to overlap the inert-gas supply portion in a plan view.

11. The plasma atomic layer deposition apparatus according to claim 8,
wherein an inert-gas supply channel through which the inert gas flows is formed between the deposition prevention member and the inert-gas supply portion.

12. The plasma atomic layer deposition apparatus according to claim 11,
wherein the inert-gas supply channel includes:
a first inert-gas supply channel through which the inert gas flows in a direction toward the second electrode; and
a second inert-gas supply channel through which the inert gas flows in a direction away from the second electrode.

13. The plasma atomic layer deposition apparatus according to claim 12,
wherein the second inert-gas supply channel has a vertical flow channel through which the inert gas flows in a vertical direction, and
a vertical part of the deposition prevention member and a vertical part of the inert-gas supply portion sandwiching the vertical flow channel are connected to each other by a fixing member.

14. The plasma atomic layer deposition apparatus according to claim 8,
wherein the plasma atomic layer deposition apparatus further has a source-gas supply portion configured to supply a source gas for forming the film on the substrate, and
the inert-gas supply portion is different from the source-gas supply portion.

15. An atomic layer deposition method forming a film on a substrate by using plasma, comprising the steps of:
(a) supplying a source gas into a film-forming container in which the substrate is arranged;
(b) after the step (a), supplying a first purge gas into the film-forming container;
(c) after the step (b), supplying a reaction gas into the film-forming container; and
(d) after the step (c), supplying a second purge gas into the film-forming container, and
the inert gas is further supplied into the film-forming container through the step (a), the step (b), the step (c) and the step (d).

16. The atomic layer deposition method according to claim 15,
wherein, while the source gas, the first purge gas, the reaction gas and the second purge gas are supplied through a first supply channel, the inert gas is supplied through a second supply channel that is different from the first supply channel.

17. The atomic layer deposition method according to claim 15,
wherein pressure variation in the film-forming container through the step (a), the step (b), the step (c) and the step (d) is smaller than pressure variation in the film-forming container in a case without the supply of the inert gas.

18. The atomic layer deposition method according to claim 15,
wherein the film formed on the substrate is a film forming a part of a protective film that protects a light emitting layer of an organic EL element.
